(19) United States
(12) Patent Application Publication
(10) Pub. No.: US 2025/0287611 A1
(43) Pub. Date: Sep. 11, 2025

(54) SEMICONDUCTOR DEVICES AND MANUFACTURING METHODS OF THE SAME

(71) Applicant: Yangtze Memory Technologies Co., Ltd., Wuhan (CN)

(72) Inventors: Huan WANG, Wuhan (CN); Chengbao ZHOU, Wuhan (CN); Liang XIAO, Wuhan (CN); Mingkang ZHANG, Wuhan (CN); Yingcheng ZHAO, Wuhan (CN)

(21) Appl. No.: 18/767,962

(22) Filed: Jul. 9, 2024

Related U.S. Application Data
(63) Continuation of application No. PCT/CN2024/080763, filed on Mar. 8, 2024.

(51) Int. Cl. H10B 80/00; H01L 23/00; H01L 25/00; H01L 25/065; H01L 25/18; H10B 12/00

(52) U.S. Cl. CPC H10B 80/00; H01L 24/08; H01L 24/80; H01L 25/0657; H01L 25/18; H01L 25/50; H10B 12/315; H01L 2224/08145; H01L 2224/80895; H01L 2224/80896; H01L 2924/1431; H01L 2924/1436

(57) ABSTRACT

The present disclosure relates to methods, devices, systems, and techniques for manufacturing contact structures in semiconductor devices, e.g., 3D memory devices such as DRAM. An example semiconductor device includes a first semiconductor structure and a second semiconductor structure connected together. The first semiconductor structure includes a first contact structure extending along a first direction and an array of memory cells. The first contact structure includes a first cross section and a second cross section both perpendicular to the first direction. The first cross section is farther away from the second semiconductor structure than the second cross section along the first direction. A size of the first cross section is smaller than a size of the second cross section.

### CROSS-REFERENCE TO RELATED APPLICATIONS

This application is a continuation of International Application No. PCT/CN2024/080763, filed on Mar. 8, 2024, the disclosure of which is hereby incorporated by reference in its entirety.

### TECHNICAL FIELD

The present disclosure relates to semiconductor devices and fabrication methods thereof.

### BACKGROUND

Semiconductor industry is driven by the need to produce smaller and faster chips. Makers of memory devices and systems also are pushing to improve scaling techniques. Dynamic random-access memory (DRAM) is a common type of memory device widely used in computer systems. Therefore, advanced techniques for mitigating problems and improving scaling of DRAM devices are desirable.

### SUMMARY

The present disclosure describes methods, devices, systems, and techniques for manufacturing contact structures in semiconductor devices, e.g., 3D memory devices such as DRAM.

One aspect of the present disclosure features a semiconductor device that includes a first semiconductor structure and a second semiconductor structure connected together. The first semiconductor structure includes a first contact structure extending along a first direction and an array of memory cells. The first contact structure includes a first cross section and a second cross section both perpendicular to the first direction. The first cross section is farther away from the second semiconductor structure than the second cross section along the first direction. A size of the first cross section is smaller than a size of the second cross section.

In some implementations, the second semiconductor structure includes a peripheral circuit associated with the array of memory cells, and the peripheral circuit is coupled to the first contact structure.

In some implementations, the size of the first cross section is a maximum size of the first cross section along a second direction perpendicular to the first direction, and the size of the second cross section is a maximum size of the second cross section along the second direction.

In some implementations, the first contact structure extends through a semiconductor layer of the first semiconductor structure, and the first contact structure is spaced from the array of memory cells along a second direction perpendicular to the first direction.

In some implementations, the semiconductor device further includes a bonding structure between the first semiconductor structure and the second semiconductor structure. The second semiconductor structure is bonded to a first side of the first semiconductor structure through the bonding structure. The bonding structure includes conductive bonding pads and at least one dielectric material isolating the conductive bonding pads in a second direction perpendicular to the first direction.

In some implementations, the first semiconductor structure further includes an interconnect layer between the first contact structure and the bonding structure along the first direction. A first end of the first contact structure is coupled to one of the conductive bonding pads of the bonding structure through the interconnect layer. A second end of the first contact structure is coupled to a first conductive contact structure on a second side of the first semiconductor structure, the second side being opposite to the first side.

In some implementations, the interconnect layer includes at least an interconnect line extending along the second direction and a vertical interconnect access (VIA) extending along the first direction. The VIA includes a third cross section and a fourth cross section both perpendicular to the first direction. The third cross section is farther away from the second semiconductor structure than the fourth cross section along the first direction. A size of the third cross section is smaller than a size of the fourth cross section.

In some implementations, at least one of the array of memory cells includes a transistor extending along the first direction and a storage structure. A first end of the storage structure is coupled to the transistor. A second end of the storage structure is coupled to a second conductive contact structure in contact with a trench. The trench extends from the second side of the first semiconductor structure into the first semiconductor structure. Both the first conductive contact structure and the second conductive contact structure include aluminum.

In some implementations, the second conductive contact structure includes a first portion, a second portion, and a third portion. The first portion and the second portion are connected by the third portion. The first portion and the second portion are perpendicular to the first direction. The first portion is in contact with a bottom of the trench. The third portion is in contact with sidewalls of the trench. The second portion is in contact with a part of the second side that is connected to the sidewalls of the trench.

In some implementations, a ratio between a first size of the trench in the first direction and a second size of the trench in the second direction is smaller than 0.5.

In some implementations, the first semiconductor structure further includes a second contact structure extending along the first direction through a semiconductor layer of the first semiconductor structure. The second contact structure is coupled to the peripheral circuit. The first contact structure is configured to transfer a control signal to and from the peripheral circuit. The second contact structure is configured to provide power to the peripheral circuit.

Another aspect of the present disclosure features a method including forming a first semiconductor structure. The first semiconductor structure includes an array of memory cells. At least one of the array of memory cells includes a transistor extending along a first direction and a storage structure coupled to the transistor. The method further includes forming a contact structure in the first semiconductor structure. The contact structure extends along the first direction. The method further includes bonding the first semiconductor structure to a second semiconductor structure. The second semiconductor structure includes a peripheral circuit associated with the array of memory cells. The contact structure is coupled to the peripheral circuit.

In some implementations, forming the first semiconductor structure that includes the array of memory cells includes forming a semiconductor body of the transistor in a semiconductor layer of the first semiconductor structure and forming a dielectric region extending through the semiconductor layer along the first direction.

In some implementations, the first semiconductor structure includes a first side and a second side opposite to the first side. The first side is closer to the semiconductor layer than the second side along the first direction. Forming the contact structure in the first semiconductor structure includes forming a contact hole in the first semiconductor structure by etching the first semiconductor structure from the first side, where the contact hole extends through the dielectric region, and forming the contact structure in the contact hole by depositing a conductive material into the contact hole.

In some implementations, the method further includes stacking the first semiconductor structure on a carrier wafer before forming the contact hole, where the second side is in contact with the carrier wafer.

In some implementations, the method further includes forming an interconnect layer in the first semiconductor structure, where the interconnect layer is coupled to the contact structure and includes at least an interconnect line extending along a second direction perpendicular to the first direction and a VIA extending along the first direction.

In some implementations, bonding the first semiconductor structure to the second semiconductor structure includes bonding the first semiconductor structure to the second semiconductor structure through a bonding structure. The bonding structure includes conductive bonding pads and at least one dielectric material isolating the conductive bonding pads in a second direction perpendicular to the first direction. The first side is between the second side and the bonding structure.

In some implementations, the method further includes forming a trench extending from the second side of the first semiconductor structure into the first semiconductor structure and forming a conductive contact structure in the trench by depositing a conductive material in the trench, where the conductive contact structure is coupled to the storage structure.

A further aspect of the present disclosure features a memory system. The memory system includes a memory device and a memory controller coupled to the memory device and configured to control the memory device. The memory device includes a first semiconductor structure and a second semiconductor structure connected together. The first semiconductor structure includes a first contact structure extending along the first direction and an array of memory cells. The first contact structure includes a first cross section and a second cross section both perpendicular to the first direction. The first cross section is farther away from the second semiconductor structure than the second cross section along the first direction. A size of the first cross section is smaller than a size of the second cross section.

In some implementations, the size of the first cross section is a maximum size of the first cross section along a second direction perpendicular to the first direction, and the size of the second cross section is a maximum size of the second cross section along the second direction.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a side view of a cross-section of an example three-dimensional (3D) semiconductor device.

FIGS. 2A-2G show an example fabrication process for manufacturing a semiconductor device.

FIG. 3 illustrates a flow chart of an example process for manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Contact structures in a semiconductor device (e.g., a DRAM device) can be configured to provide interconnections between components of the semiconductor device or to couple a component of the semiconductor device to an outside circuit (e.g., for pad-out purposes). Manufacturing of the contact structures can include forming contact holes in the semiconductor device by an etching process and depositing a conductive material into the contact holes. In some implementations, it can be difficult to form a longer contact structure (e.g., in a vertical direction) and a shorter contact structure (e.g., in the vertical direction) by a same manufacturing process or manufacturing loop. One of the reasons is that when forming a contact hole for the shorter contact structure, the etching process in the manufacturing loop may cause loss of a conductive material such as Tungsten (W) in the semiconductor device. However, forming the longer contact structure and the shorter contact structure using multiple etching masks and multiple etching processes may increase the manufacturing cost and reduce the production yield.

Implementations of the present disclosure provide techniques for forming a semiconductor device that includes a first semiconductor structure and a second semiconductor structure connected together. Contact structures that extend through the first semiconductor structure and vertical interconnect access (VIA) contacts in an interconnect layer of the first semiconductor structure can be formed in a same manufacturing loop. For example, the contact structures and the VIA contacts can be formed before the first semiconductor structure is bonded to the second semiconductor structure.

Implementations of the present disclosure can provide one or more of the following technical advantages and/or benefits. Contact structures of different sizes along a vertical direction can be formed by different manufacturing loops, thereby avoiding a Tungsten loss problem. A bottom top metal (BTM) and a bottom top VIA (BTV) coupled to the BTM can be combined into one conductive structure, thereby reducing the manufacturing cost and increasing the production yield. Furthermore, the conductive structure that replaces the BTM and the BTV can be made of aluminum (Al) instead of W, thereby further reducing the manufacturing cost.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

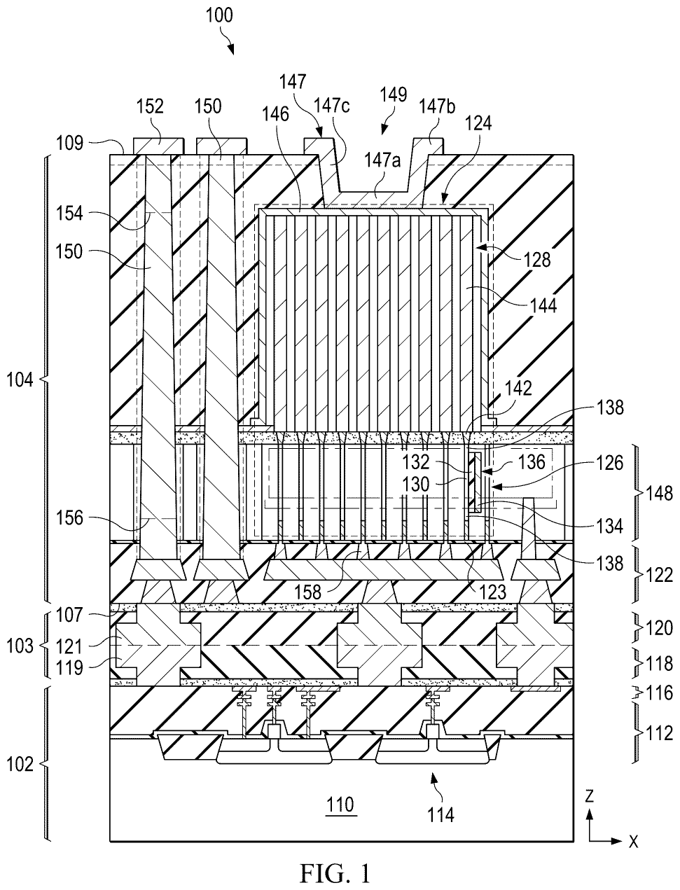

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. The 3D semiconductor device 100 includes a semiconductor structure 102 and a semiconductor structure 104 connected together. In some implementations, the 3D semiconductor device 100 is a bonded chip including the semiconductor structure 104 stacked over the semiconductor structure 102. The semiconductor structures 102 and 104 can be jointed at a bonding structure 103 therebetween. The semiconductor structure 104 can have two sides 107 and 109. The side 107 (e.g., the bottom surface) is closer to the semiconductor structure 102. The side 109 (e.g., the top surface) is farther away from the semiconductor structure 102 and is opposite to the side 107.

It is noted that X, Y, and Z axes (also referred to as X, Y, and Z directions) are included in FIG. 1 to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 1, the semiconductor structure 102 can include a substrate 110, which can include silicon (e.g., single crystalline silicon, c-Si), SiGe, GaAs, Ge, SOI, or any other suitable materials. The semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the semiconductor structure 102 can be also formed on a semiconductor die that can be referred to as a control die or a CMOS die 102.

In some implementations, the semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and vertical interconnect access (VIA) contacts. The interconnect layer 116 can further include one or more interlayer dielectric (ILD) layers in which the interconnect lines and VIA contacts can form. That is, the interconnect layer 116 can include interconnect lines and VIA contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the bonding structure 103 can include a bonding layer (also referred to as a bonding structure) 118 and a bonding layer (also referred to as a bonding structure) 120 jointed at bonding interface 106 therebetween. The bonding layer 118 can be above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. The bonding layer 120 can be above the bonding layer 118. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

In some implementations, the bonding layer 118 can be considered as a part of the semiconductor structure 102, and the bonding layer 120 can be considered as a part of the semiconductor structure 104. The semiconductor structure 104 can be bonded on top of the semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 and the bottom surface of the bonding layer 120.

In some implementations, the semiconductor structure 104 further includes an interconnect layer 122 above the bonding layer 120 to transfer electrical signals. The interconnect layer 122 can include a plurality of interconnects, such as mid end of line (MEOL) interconnects and back end of line (BEOL) interconnects. The plurality of interconnects in the interconnect layer 122 can includes lateral interconnect lines and VIA contacts. In some implementations, the interconnects in interconnect layer 122 also include local interconnects, such as the bit lines 123 and word line contacts (not shown). The interconnect layer 122 can further include one or more ILD layers in which the interconnect lines and VIA contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact. In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (e.g., in the Z direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the X direction). In some implementations, the gate dielectric 132 abuts one side of the semiconductor body 130, and the gate electrode 134 abuts the gate dielectric 132.

As shown in FIG. 1, in some implementations, the semiconductor body 130 has two ends (the upper end and lower end in FIG. 1) in the vertical direction (e.g., the Z direction), and at least one end (e.g., the lower end) extends beyond gate dielectric 132 in the vertical direction (e.g., the Z direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (e.g., the Z direction) into ILD layers. That is, the semiconductor body 130 can have a larger vertical dimension (e.g., the depth) than that of the gate electrode 134 (e.g., in the Z direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the semiconductor body 130, respectively, in the vertical direction (e.g., the Z direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive Z direction and a second terminal opposite the first terminal in the negative Z direction, as shown in FIG. 1.

In some implementations, the semiconductor structure 104 further includes a substrate 148 disposed above the interconnect layer 122. The semiconductor body 130 can be formed from the substrate 148 (e.g., by etching or epitaxy) and thus, has the same semiconductor material as the substrate 148. The semiconductor body 130 can include semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the Y direction) as a word line, the second semiconductor structure 104 of the 3D semiconductor device 100 can also include a plurality of word lines each extending in the word line direction (e.g., the Y direction). Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128.

As shown in FIG. 1, in some implementations, a capacitor 128 includes a first electrode 144 above and coupled to the source or drain 138 of vertical transistor 126, e.g., the upper end of the semiconductor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (e.g., in the Z direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative Z direction and a second end opposite the first end in the positive Z direction, as shown in FIG. 1. In some implementations, the first end of the capacitor 128 is coupled to the first terminal of the vertical transistor 126 via an ohmic contact (e.g., the capacitor contact 142 made of a metal silicide material).

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, the second semiconductor structure 104 can further include a contact structure 147 (also referred to as a pad-out contact structure or a conductive contact structure) in contact with the common plate 146 for coupling the capacitors 128 to outside circuits, e.g., for pad-out purposes. In some implementations, as shown in FIG. 1, the contact structure 147 can be a conductive pad that is in contact with a trench 149. The trench 149 can extend from the side 109 into the semiconductor structure 104 and expose the common plate 146. In some implementations, a ratio between a first size of the trench 149 in the vertical direction (e.g., the Z direction) and a second size of the trench 149 in a horizontal direction (e.g., the X direction) is smaller than 0.5. For example, the ratio can be 0.3. The contact structure 147 is in contact with a bottom surface (e.g., part of the common plate 146) and sidewalls of the trench 149. The contact structure 147 can also cover a part of the side 109 as shown in FIG. 1. In some implementations, as shown in FIG. 1, the contact structure 147 includes a first portion 147a, a second portion 147b, and a third portion 147c. The first portion 147a and the second portion 147b are connected by the third portion 147c. The first portion 147a and the second portion 147b extends in the X-Y plane (e.g., perpendicular to the Z direction). The first portion 147a is in contact with a bottom of the trench 149. The third portion 147c is in contact with sidewalls of the trench 149. The second portion 147b is in contact with a part of the side 109 that is connected to the sidewalls of the trench 149. In some implementations (not shown in FIG. 1), the contact structure 147 can include one or more conductive pads (also referred to as bottom top metals (BTMs)) that are disposed on the side 109 and one or more conductive VIAs (also referred to as bottom top VIAs (BTVs)) that extend along the Z direction and connect the conductive pads and the common plate 146. In some implementations, the contact structure 147 includes conductive materials including, but not limited to W, Co, Cu, Al, TiN, TaN, polysilicon, silicides, or any combination thereof.

As shown in FIG. 1, the semiconductor structure 104 can further include one or more contact structures 150 (also referred to as a pad-out contact structure) extending along the Z direction. The contact structures 150 can also be referred to as through silicon contacts (TSCs) since each contact structure 150 can extend from the side 109 into the semiconductor structure 104 and extend through the substrate 148. In some implementations, the contact structures 150 can be spaced from the array of DRAM cells 124 along a horizontal direction (e.g., the X direction). In some implementations, the semiconductor structure 104 can include a dielectric spacer (e.g., having silicon oxide) between each contact structure 150 and the substrate 148 to electrically separate the contact structure 150 and the substrate 148. One end of the contact structure 150 can be connected to a conductive pad 152 disposed on the side 109, and another end of the contact structure 150 can be coupled to the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contact structures 150 and conductive pads 152. The contact structure 150 and the conductive pad 152 can include conductive materials including, but not limited to W, Co, Cu, Al, TIN, TaN, polysilicon, silicides, or any combination thereof. The contact structure 150 and the conductive pad 152 can include either the same conductive material or different conducive materials. In some implementations, the contact structure 150 includes W, and the conductive pad 152 includes Al. The contact structures 150 can be configured to transfer electrical signals between the 3D semiconductor device 100 and outside circuits, e.g., for pad-out purposes. For example, one contact structure 150 can be configured to transfer a control signal to and from the peripheral circuit 112, and another one contact structure 150 can be configured to provide power to the peripheral circuit 112.

In some implementations, each of the contact structures 150 can have a shape like a cylinder or a truncated cone that tapers along the Z direction. For example, a cross section of a top portion of the contact structure 150 can have a smaller size than another cross section of a bottom portion of the contact structure 150. As shown in FIG. 1, the contact structure 150 can have a cross section 154 and a cross section 156 both perpendicular to the Z direction. The cross section 154 is farther away from the semiconductor structure 102 than the cross section 156 along the Z direction. In other words, the cross section 154 is closer to the side 109 of the semiconductor structure 104 than the cross section 156 along the Z direction. A size of the cross section 154 is smaller than a size of the cross section 156. In some implementations, the size of the cross section 154 is a maximum size of the cross section 154 along a horizontal direction (e.g., the X direction), and the size of the cross section 156 is a maximum size of the cross section 156 along the same horizontal direction (e.g., the X direction).

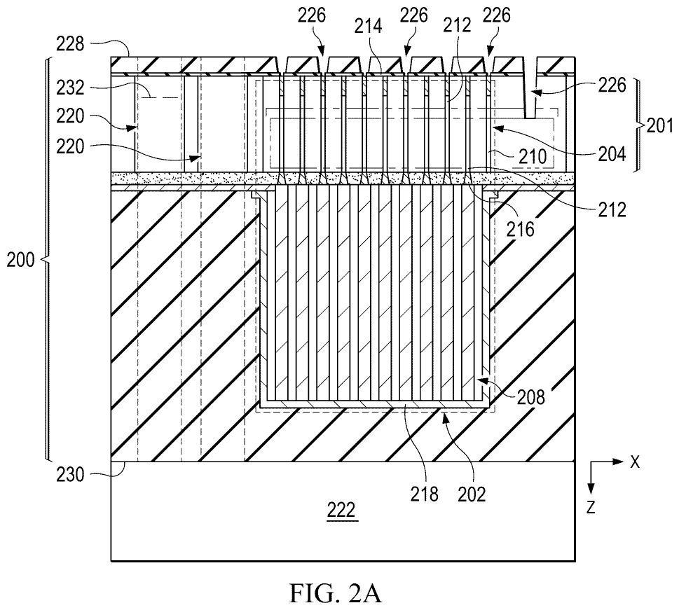

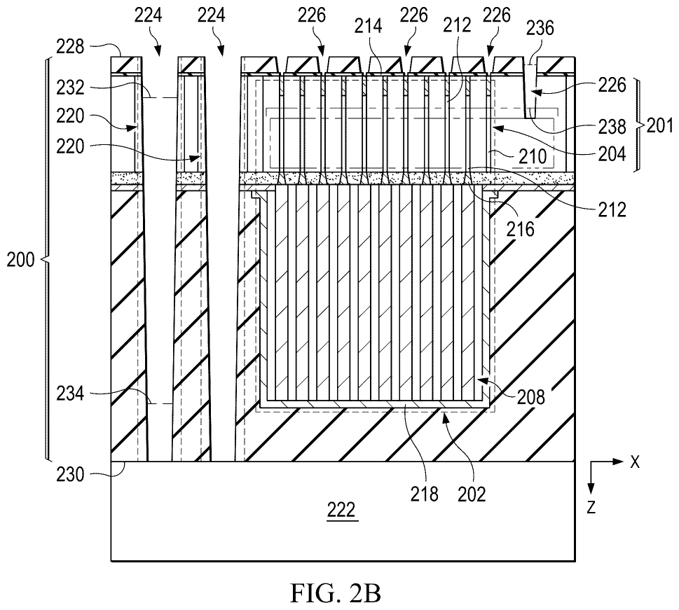

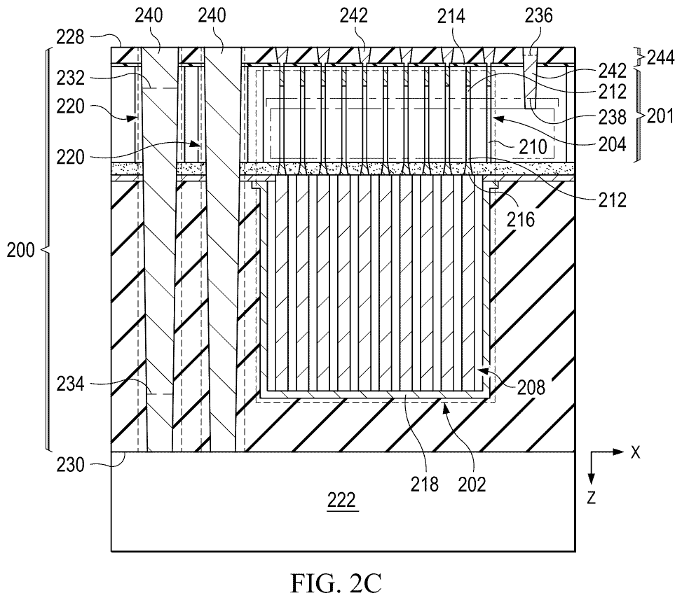

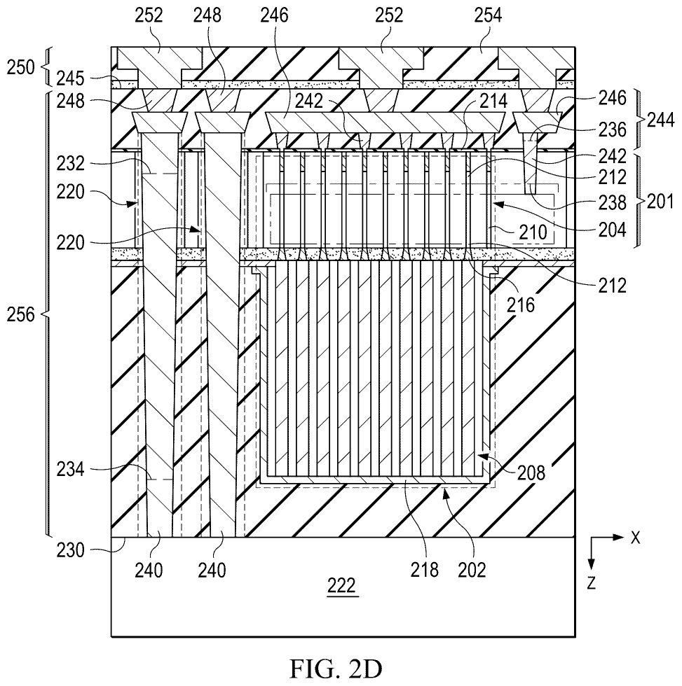

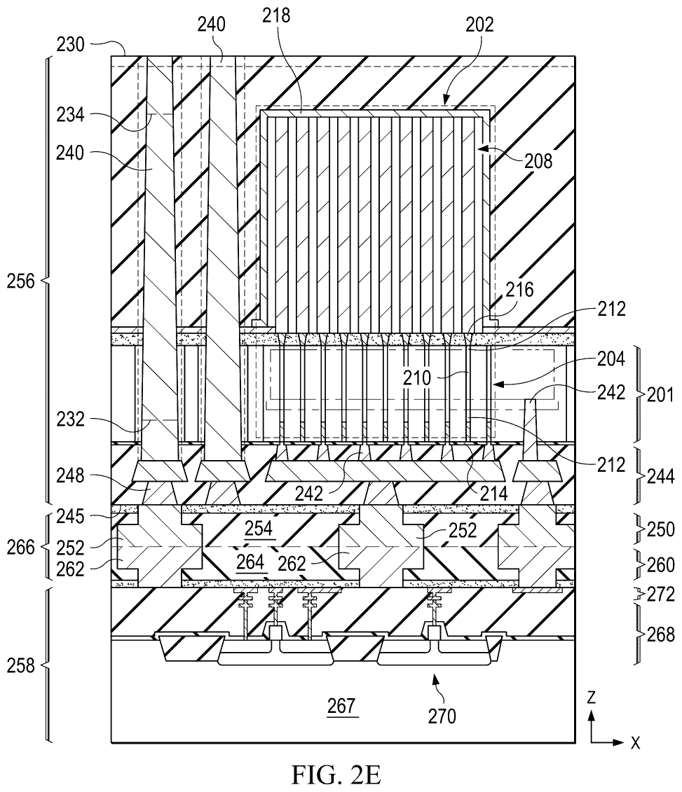

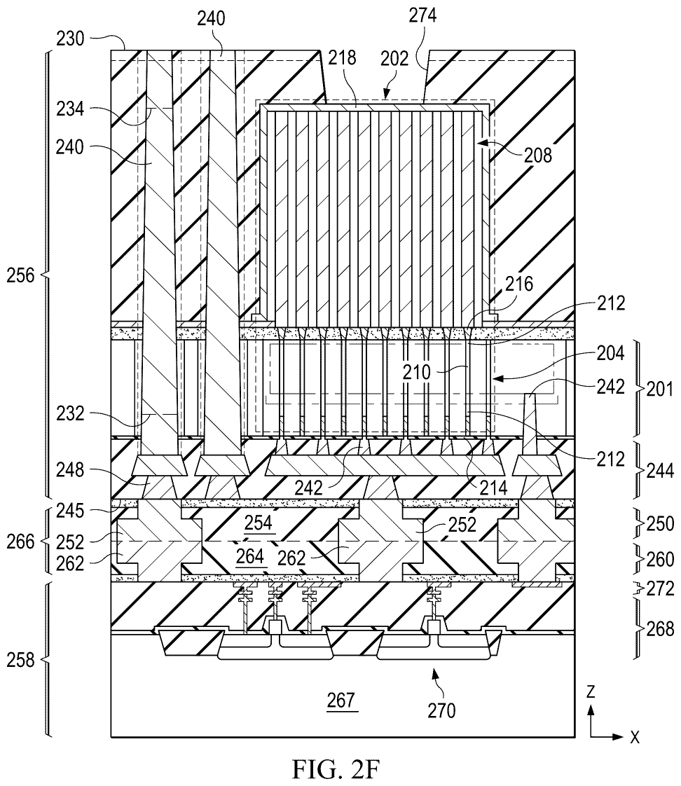

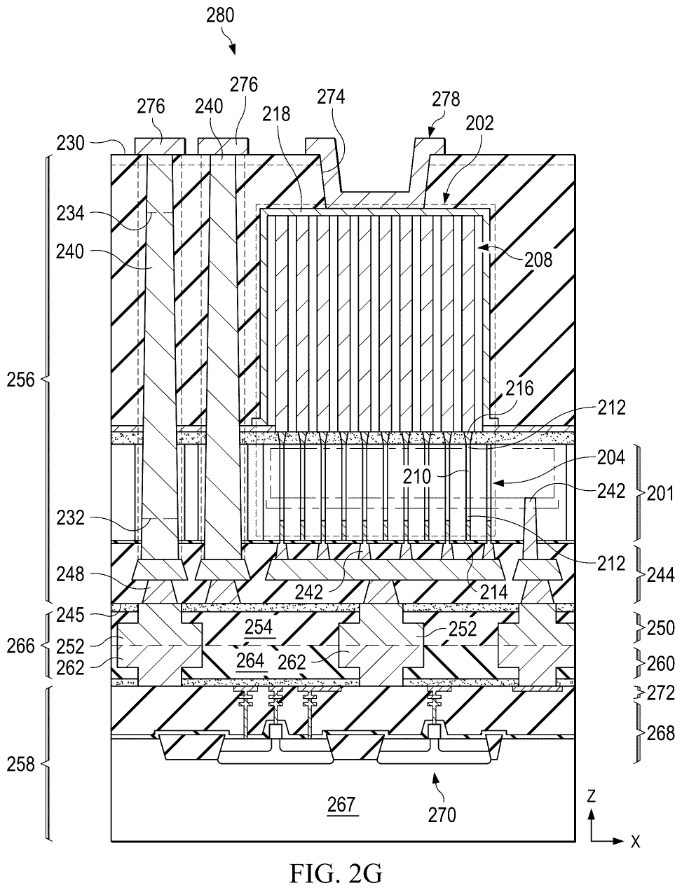

In some implementations, a VIA in the interconnect layer 122 (e.g., VIA 158), which can be referred to as VIA contact or VIA contact structure, also has a shape like a cylinder or a truncated cone that tapers along the Z direction. For example, the VIA 158 can have a top cross section and a bottom cross section (not shown) both perpendicular to the Z direction. The top cross section of the VIA 158 is farther away from the semiconductor structure 102 than the bottom cross section of the VIA 158 along the Z direction. A size of the top cross section of the VIA 158 is smaller than a size of the bottom cross section of the VIA 158. In some implementations, for example, as described later with further details with respect to FIG. 2C, the VIAs in the interconnect layer 122 and the contact structures 150 are formed by the same manufacturing procedure or manufacturing loop.

FIGS. 2A-2G show an example fabrication process for manufacturing a semiconductor device (e.g., the semiconductor device 100 of FIG. 1).

As shown in FIG. 2A, a semiconductor structure 200 can be formed. The semiconductor structure 200 can be an example of the semiconductor structure 104 of FIG. 1, except that some pad-out contact structures (e.g., the contact structure 147, the contact structures 150, and the conductive pads 152 of FIG. 1) and at least a part of an interconnect layer (e.g., the interconnect layer 122 of FIG. 1) are not formed in the semiconductor structure 200 yet.

The semiconductor structure 200 can be formed by any suitable semiconductor manufacturing techniques. The semiconductor structure 200 can include a semiconductor layer 201 and an array of DRAM cells 202 (e.g., DRAM cells 124 of FIG. 1). The semiconductor layer 201 can be a substrate (e.g., substrate 148 of FIG. 1). The array of DRAM cells 202 include vertical transistors 204 (e.g., vertical transistor 126 of FIG. 1) and capacitors 208 (e.g., capacitor 128 of FIG. 1). Each DRAM cell 202 can include a vertical transistor 204 and a corresponding capacitor 208 coupled to the vertical transistor 204. Each vertical transistor 204 can be a MOSFET used to switch a respective DRAM cell 202. In some implementations, each vertical transistor 204 includes a respective semiconductor body 210 (e.g., semiconductor body 130 of FIG. 1) extending vertically (e.g., in the Z direction) and a respective gate structure (e.g., gate structure 136 of FIG. 1, not shown in FIG. 2A) in contact with one side of the semiconductor body 210. The semiconductor bodies 210 can be formed from the substrate 201 (e.g., by etching or epitaxy) and thus, have the same semiconductor material as the substrate 201. For example, the semiconductor bodies 210 can be formed by forming trenches in the substrate 201 that extend along the lateral directions (e.g., the X direction and the Y direction) during an etching process. The gate structures of the vertical transistors 204 can be formed by depositing a gate dielectric layer and a conductive layer on each semiconductor body 210.

As shown in FIG. 2A, the semiconductor body 210 has two ends in the vertical direction (e.g., the Z direction). The vertical transistor 204 can further include a source and a drain (both referred to as 212 as their locations may be interchangeable) disposed at the two ends (an upper end and a lower end) of the semiconductor body 210, respectively, in the vertical direction (e.g., the Z direction). In some implementations, the source and drain 212 (e.g., source and drain 138 of FIG. 1) can be formed by doping the semiconductor body 210 of each vertical transistor 204 with a dopant (e.g., a P-type dopant or an N-type dopant). In some implementations, for each vertical transistor 204, one of the source and the drain 212 (e.g., at the lower end in FIG. 2A) is coupled to one of the capacitors 208, and the other one of source and drain 212 (e.g., at the upper end in FIG. 2A) is coupled to a bit line 214 (e.g., bit line 123 of FIG. 1) extending along the X direction. The array of DRAM cells 202 can be between the bit line 214 and the capacitors 208 along the Z direction.

In some implementations, each of the capacitors 208 can be a vertical capacitor including a first capacitor electrode, a second capacitor electrode, and a capacitor dielectric stacked vertically (e.g., the Z direction). The capacitors 208 can be formed by forming holes (e.g., by etching) extending in the Z direction and being adjacent to the vertical transistors 204. For each hole, the first capacitor electrode (e.g., a first conductive layer) is formed on the inner surface of the hole, and then the capacitor dielectric (e.g., a dielectric layer in contact with the first conductive layer) and the second capacitor electrode (e.g., a second conductive layer in contact with the dielectric layer) are formed. Each capacitor 208 includes the dielectric layer sandwiched between the first capacitor electrode and the second capacitor electrode. In some implementations, each first capacitor electrode is coupled to source or drain 212 of a respective vertical transistor 204 in the same DRAM cell via a respective capacitor contact 216 (e.g., capacitor contact 142 of FIG. 1), while the second capacitor electrodes are coupled to a common plate 218 (e.g., common plate 146 of FIG. 1). The semiconductor structure 200 can also include a plurality of word lines (e.g., word lines 134 of FIG. 1, not shown in FIG. 2A) each extending in the word line direction (e.g., the Y direction). Each word line can be coupled to a row of DRAM cells 202.

The substrate 201 can include one or more isolation structures 220 extending through the substrate 201 along the Z direction. Each isolation structure 220 can include dielectric materials including, but not limited to, silicon oxide, silicon nitride, silicon oxynitride, low-k dielectrics, or any combination thereof. Thus, the isolation structures 220 can also be referred to as dielectric regions. In some implementations, the isolation structures 220 can be formed by etching off the substrate 201, which can be performed in the same etching process for manufacturing the semiconductor bodies 210, to form holes that extend through the substrate 201 and then filling the dielectric material into the holes. One or more pad-out contact structures each extending through a corresponding isolation structure 220 along the Z direction can be formed later (e.g., as described with respect to FIGS. 2A-2C). The isolation structure 220 can surround a pad-out contact structure and isolate the pad-out contact structure from the substrate 201. In some implementations, the dielectric material of the isolation structure 220 (rather than the silicon of the substrate 201) will be etched off when forming the pad-out contact structures. The etching process of the isolation structure 220 can be faster than that of the substrate 201, thereby improving the efficiency of the fabrication process.

As shown in FIG. 2A, the semiconductor structure 200 can be stacked on a carrier wafer 222. The semiconductor structure 200 can bonded to the carrier wafer 222 using any suitable bonding techniques. For example, the semiconductor structure 200 can be bonded to the carrier wafer 222 through an adhesive layer (not shown) disposed therebetween. The adhesive layer can include any suitable types of adhesives. In some implementations, the semiconductor structure 200 can be bonded to the carrier wafer 222 using a direct bonding technology (e.g., forming bonding between surfaces without using intermediate layers, such as solder or adhesives). The carrier wafer 222 can provide physical support and protection to the semiconductor structure 200 during the fabrication process.

As shown in FIG. 2B, contact holes 224 and VIA holes 226 extending along the Z direction are formed. Contact holes 224 extend through semiconductor structure 200. The semiconductor structure 200 can include a first side 228 and a second side 230 opposite to the first side 228. The first side 228 is closer to the substrate 201 than the second side 230 along the Z direction. The second side 230 can be in contact with the carrier wafer 222. In some implementations, the contact holes 224 can be formed by etching off the dielectric material in the isolation structures 220 of the semiconductor structure 200 from the first side 228. The contact holes 224 extend through corresponding isolation structures 220 from the first side 228 to the second side 230. VIA holes 226 also can be formed by etching off the semiconductor structure 200 from the first side 228. VIA holes 226 can extend from the first side 228 into the semiconductor structure 200. In some implementations, each contact hole 224 can have a top cross section 232 and a bottom cross section 234 both perpendicular to the Z direction. The top cross section 232 is closer to the first side 228 than the bottom cross section 234 along the Z direction. A size of the top cross section 232 is larger than a size of the bottom cross section 234. In some implementations, each VIA hole 226 can have a top cross section 236 and a bottom cross section 238 both perpendicular to the Z direction. The top cross section 236 is closer to the first side 228 than the bottom cross section 238 along the Z direction. A size of the top cross section 236 is larger than a size of the bottom cross section 238.

As shown in FIG. 2C, contact structures 240 can be formed by depositing a conductive material into the contact holes 224, and VIAs 242 can be formed by depositing a conductive material into the VIA holes 226. In some implementations, the VIAs 242 and the contact structures 240 are formed by the same manufacturing procedure or the same manufacturing loop. The conductive materials can include, but are not limited to W, Co, Cu, Al, TiN, TaN, polysilicon, silicides, or any combination thereof. Contact structures 240 can be examples of contact structures 150 of FIG. 1. VIAs 242 can be examples of VIAs 158 of FIG. 1. VIAs 242 can belong to an interconnect layer 244 (e.g., the interconnect layer 122 of FIG. 1).

As shown in FIG. 2D, a semiconductor structure 256 can be formed from the semiconductor structure 200 by forming other parts of the interconnect layer 244, such as interconnect lines 246 extending along a horizontal direction (e.g., the X direction) and VIAs 248 extending along the vertical direction (e.g., the Z direction), on top of the semiconductor structure 200. The interconnect layer 244 can be coupled to the contact structures 240. VIAs 242 and VIAs 248 can be made of different materials. For example, VIAs 242 can be made of W, while VIAs 248 can be made of Cu. In some implementations, a bonding layer (also referred to as a bonding structure) 250 can be formed on top of the interconnect layer 244. As shown in FIG. 2D, the top of the interconnect layer 244 can be considered as a side 245 of the semiconductor structure 256. The side 245 is opposite to the side 230. The side 245 is closer to the substrate 201 than the side 230 along the Z direction. The bonding layer 250 can include conductive bonding pads 252 and a dielectric material 254 isolating the conductive bonding pads 252 in a horizontal direction (e.g., the X direction). The semiconductor structure 256 can be an example of the semiconductor structure 104 of FIG. 1.

As shown in FIG. 2E, the carrier wafer 222 can be removed or de-bonded from the semiconductor structure 256. The semiconductor structure 256 can be flipped and bonded to a semiconductor structure 258. For example, the semiconductor structure 256 can be bonded to the semiconductor structure 258 through a bonding structure 266. The bonding structure 266 is formed by the bonding layer 250 and a bonding layer (also referred to as a bonding structure) 260 jointed at a bonding interface 269. The bonding layer 260 is between the bonding layer 250 and the semiconductor structure 258. The bonding layer 260 can include conductive bonding pads 262 and a dielectric material 264 isolating the conductive bonding pads 262 in a horizontal direction (e.g., the X direction). In some implementations, the bonding layer 250 can be bonded to the bonding layer 260 using a direct bonding technology (e.g., forming bonding between surfaces without using intermediate layers, such as solder or adhesives) and can obtain metal-metal bonding and dielectric-dielectric bonding simultaneously. That is, the conductive bonding pads 252 in the bonding layer 250 are bonded to the conductive bonding pads 262 in the bonding layer 260, and the dielectric material 254 in the bonding layer 250 is bonded to the dielectric material 264 in the bonding layer 260. The bonding layer 250 can be an example of the bonding layer 120 of FIG. 1. The bonding layer 260 can be an example of the bonding layer 118 of FIG. 1.

In some implementations, the semiconductor structure 256 and the semiconductor structure 258 can be fabricated in parallel. The semiconductor structure 258 can be an example of the semiconductor structure 102 of FIG. 1. For example, the semiconductor structure 258 can include a substrate 267 and peripheral circuits 268 on and/or in the substrate 267. The peripheral circuits 268 can be an example of the peripheral circuits 112 of FIG. 1. In some implementations, the peripheral circuits 268 include a plurality of transistors 270 (e.g., planar transistors and/or 3D transistors). In some implementations, the semiconductor structure 258 further includes an interconnect layer 272 above the peripheral circuits 268 to transfer electrical signals to and from the peripheral circuits 268. In some implementations, the peripheral circuits 268 can be configured to control the array of DRAM cells 202. For example, the peripheral circuits 268 can include a word line driver and/or a bit line driver for the array of DRAM cells 202. The peripheral circuits 268 can be coupled to the DRAM cells 202 through the interconnect layer 272, the bonding structure 266, and the interconnect layer 244.

As shown in FIG. 2F, a trench 274 can be formed by an etching process. The trench 274 can extend from the side 230 of the semiconductor structure 256 into the semiconductor structure 256. The trench 274 can expose the common plate 218 that is coupled to the capacitors 208. The trench 274 can be an example of the trench 149 of FIG. 1.

As shown in FIG. 2G, a semiconductor device 280 is formed. The semiconductor device 280 includes the semiconductor structure 256, the bonding structure 266, and the semiconductor structure 258. The semiconductor structure 256 includes conductive pads 276 and contact structure 278. The conductive pads 276 can be formed by depositing a conductive material on top of the side 230. Each conductive pad 276 can be connected to an end (e.g., an end on the top) of a corresponding contact structure 240. The contact structure 278 can be formed by depositing a conductive material in the trench 274 and on top of the side 230. The conductive pads 276 can be an example of the conductive pads 152 of FIG. 1. The contact structure 278 can be an example of the contact structure 147 of FIG. 1. Each of the conductive pads 276 and the contact structure 278 can be made of conductive materials including, but not limited to W, Co, Cu, Al, TiN, TaN, polysilicon, silicides, or any combination thereof. In some implementations, the conductive pads 276 and the contact structure 278 are made of Al instead of W, thereby reducing the cost of the manufacturing process. While FIG. 2G shows two conductive pads 276 and one contact structure 278, it is understood that any suitable number of conductive pads and contact structures can be formed. For example, multiple contact structures 278 can be formed and coupled to the common plate 218 thereby enlarging a contact area between the contact structures 278 and the common plate 218 and reducing the resistance caused by the contact structures 278. It is also understood that while the conductive pads 276 and the contact structure 278 illustrated by FIG. 2G are merely examples, any other suitable conductive pads and contact structure that are respectively coupled to the contact structures 240 and the common plate 218 can be formed.

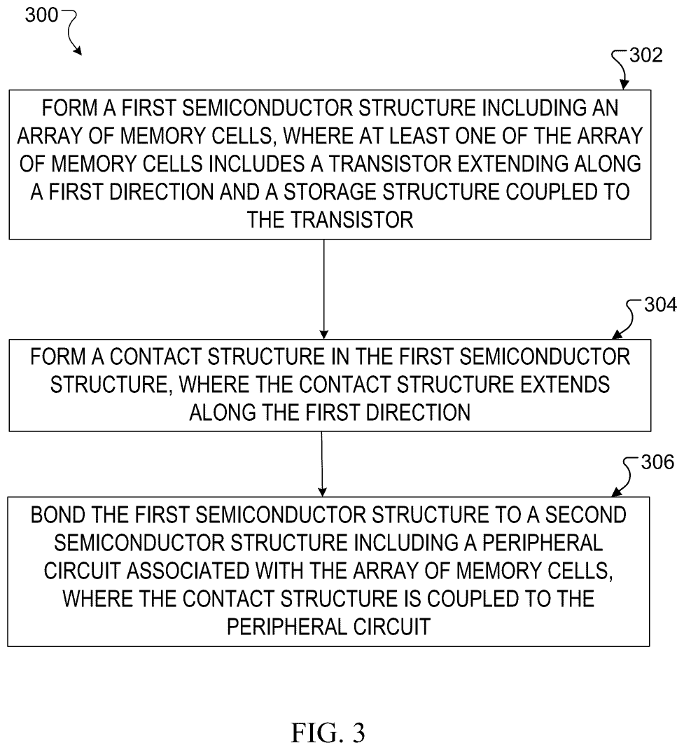

FIG. 3 illustrates a flow chart of an example process 300. The process 300 can be performed to from a semiconductor device (e.g., a DRAM). The semiconductor device can be, for example, the semiconductor device 100 of FIG. 1 or the semiconductor device 280 of FIG. 2G. The process 300 can be described in view of FIGS. 2A-2G. The process 300 can include the fabrication process of forming the semiconductor structures in FIGS. 2A-2G. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a first semiconductor structure (e.g., the semiconductor structure 256 of FIGS. 2D-2G) is formed. The first semiconductor structure can include an array of memory cells (e.g., the array of DRAM cells 202 of FIG. 2A). At least one of the array of memory cells includes a transistor (e.g., the vertical transistor 204) extending along a first direction (e.g., the Z direction) and a storage structure (e.g., the capacitor 208 of FIG. 2A) coupled to the transistor.

In some implementations, forming the first semiconductor structure includes forming a semiconductor body (e.g., the semiconductor body 210 of FIG. 2A) of the transistor in a semiconductor layer (e.g., the substrate 201) of the first semiconductor structure.

In some implementations, forming the first semiconductor structure further includes forming a dielectric region (e.g., the isolation structure 220 of FIG. 2A) extending through the semiconductor layer along the first direction.

At operation 304, a contact structure (e.g., the contact structure 150 of FIG. 1 or the contact structure 240 of FIG. 2C) in the first semiconductor structure is formed. The contact structure extends along the first direction. In some implementations, the first semiconductor structure comprises a first side (e.g., the side 245 of FIG. 2D) and a second side (e.g., the side 230 of FIG. 2D) opposite to the first side. The first side can be closer to the semiconductor layer than the second side along the first direction.

In some implementations, forming the contact structure in the first semiconductor structure includes forming a contact hole (e.g., the contact hole 224 of FIG. 2B) in the first semiconductor structure by etching the first semiconductor structure from the first side. In some implementations, the contact hole can extend through the dielectric region. In some implementations, forming the contact structure in the first semiconductor structure further includes depositing a conductive material into the contact hole.

In some implementations, the first semiconductor structure can be stacked on a carrier wafer (e.g., the carrier wafer 222 of FIG. 2A) before the contact hole is formed. The carrier wafer can provide physical support and protection to the first semiconductor structure during the fabrication process. In some implementations, the second side (e.g., the side 230) of the first semiconductor structure is in contact with the carrier wafer.

In some implementations, an interconnect layer (e.g., the interconnect layer 244 of FIG. 2D) can be formed in the first semiconductor structure. The interconnect layer can be coupled to the contact structure. The interconnect layer can include at least an interconnect line (e.g., the interconnect lines 246 of FIG. 2D) extending along a second direction perpendicular to the first direction and a VIA (e.g., one of the VIAs 242 or 248 of FIG. 2D) extending along the first direction.

At operation 306, the first semiconductor structure is bonded to a second semiconductor structure (e.g., the semiconductor structure 258 of FIG. 2E). The second semiconductor structure can include a peripheral circuit (e.g., the peripheral circuit 268 of FIG. 2E) associated with the array of memory cells. The contact structure is coupled to the peripheral circuit. In some implementations, the carrier wafer can be removed or de-bonded from the first semiconductor structure. In some implementations, the first semiconductor structure can be bonded to the second semiconductor structure through a bonding structure (e.g., the bonding structure 266 of FIG. 2E). The bonding structure includes conductive bonding pads (e.g., the conductive bonding pads 252 and 262) and at least one dielectric material (the dielectric materials 254 and 264) isolating the conductive bonding pads in a second direction perpendicular to the first direction. In some implementations, the first side (e.g., the side 245 of FIG. 2E) of the first semiconductor structure is between the second side (e.g., the side 230 of FIG. 2E) of the first semiconductor structure and the bonding structure.

In some implementations, the process 300 further includes forming a trench (e.g., the trench 274 of FIG. 2F) extending from the second side of the first semiconductor structure into the first semiconductor structure. In some implementations, the process 300 further includes forming a conductive contact structure (e.g., the contact structure 278 of FIG. 2G) in the trench. For example, the conductive contact structure can be formed by depositing a conductive material (e.g., Al) in the trench. The conductive contact structure can be coupled to the storage structure.

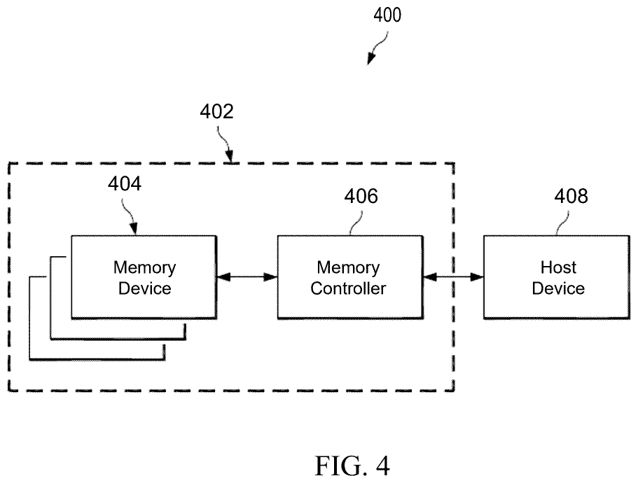

FIG. 4 illustrates a block diagram of an example system 400. The system 400 can have one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 4, the system 400 can include a host device 408 and a memory system 402 having one or more memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more memory devices 404.

A memory device 404 can be any memory device disclosed herein, such as a memory device (e.g., a DRAM device) as shown in FIGS. 1 and 2A-2G. In some implementations, a memory device 404 includes a NAND Flash memory. Memory controller 406 (a.k.a., a controller circuit) is coupled to memory device 404 and host device 408. Consistent with implementations of the present disclosure, memory device 404 can include a plurality of conductive interconnections through a cover layer that are in contact with conductive pads in a conductive pad layer, and memory controller 406 can be coupled to memory device 404 through at least one of the plurality of conductive interconnections. Memory controller 406 is configured to control memory device 404. For example, memory controller 406 may be configured to operate a plurality of channel structures via word lines. Memory controller 406 can manage data stored in memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program (or write) operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCI express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,.+−. 10%, .+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising a first semiconductor structure and a second semiconductor structure connected together, wherein:
the first semiconductor structure comprises a first contact structure extending along a first direction and an array of memory cells;
the first contact structure comprises a first cross section and a second cross section both perpendicular to the first direction;
the first cross section is farther away from the second semiconductor structure than the second cross section along the first direction; and
a size of the first cross section is smaller than a size of the second cross section.

2. The semiconductor device of claim 1, wherein the second semiconductor structure comprises a peripheral circuit associated with the array of memory cells, and the peripheral circuit is coupled to the first contact structure.

3. The semiconductor device of claim 1, wherein the size of the first cross section is a maximum size of the first cross section along a second direction perpendicular to the first direction, and the size of the second cross section is a maximum size of the second cross section along the second direction.

4. The semiconductor device of claim 1, wherein the first contact structure extends through a semiconductor layer of the first semiconductor structure, and the first contact structure is spaced from the array of memory cells along a second direction perpendicular to the first direction.

5. The semiconductor device of claim 1, further comprising a bonding structure between the first semiconductor structure and the second semiconductor structure, wherein:
the second semiconductor structure is bonded to a first side of the first semiconductor structure through the bonding structure; and
the bonding structure comprises conductive bonding pads and at least one dielectric material isolating the conductive bonding pads in a second direction perpendicular to the first direction.

6. The semiconductor device of claim 5, wherein:
the first semiconductor structure further comprises an interconnect layer between the first contact structure and the bonding structure along the first direction;
a first end of the first contact structure is coupled to one of the conductive bonding pads of the bonding structure through the interconnect layer; and
a second end of the first contact structure is coupled to a first conductive contact structure on a second side of the first semiconductor structure, the second side being opposite to the first side.

7. The semiconductor device of claim 6, wherein:
the interconnect layer comprises at least an interconnect line extending along the second direction and a vertical interconnect access (VIA) extending along the first direction;
the VIA comprises a third cross section and a fourth cross section both perpendicular to the first direction;
the third cross section is farther away from the second semiconductor structure than the fourth cross section along the first direction; and
a size of the third cross section is smaller than a size of the fourth cross section.

8. The semiconductor device of claim 6, wherein:
at least one of the array of memory cells comprises a transistor extending along the first direction and a storage structure;
a first end of the storage structure is coupled to the transistor;
a second end of the storage structure is coupled to a second conductive contact structure in contact with a trench, the trench extending from the second side of the first semiconductor structure into the first semiconductor structure; and
both the first conductive contact structure and the second conductive contact structure comprise aluminum.

9. The semiconductor device of claim 8, wherein:
the second conductive contact structure comprises a first portion, a second portion, and a third portion;
the first portion and the second portion are connected by the third portion;
the first portion and the second portion are perpendicular to the first direction;
the first portion is in contact with a bottom of the trench;
the third portion is in contact with sidewalls of the trench; and
the second portion is in contact with a part of the second side that is connected to the sidewalls of the trench.

10. The semiconductor device of claim 8, wherein a ratio between a first size of the trench in the first direction and a second size of the trench in the second direction is smaller than 0.5.

11. The semiconductor device of claim 2, wherein:
the first semiconductor structure further comprises a second contact structure extending along the first direction through a semiconductor layer of the first semiconductor structure;
the second contact structure is coupled to the peripheral circuit;
the first contact structure is configured to transfer a control signal to and from the peripheral circuit; and
the second contact structure is configured to provide power to the peripheral circuit.

12. A method, comprising:
forming a first semiconductor structure comprising an array of memory cells, wherein at least one of the array of memory cells comprises a transistor extending along a first direction and a storage structure coupled to the transistor;
forming a contact structure in the first semiconductor structure, wherein the contact structure extends along the first direction; and
bonding the first semiconductor structure to a second semiconductor structure comprising a peripheral circuit associated with the array of memory cells, wherein the contact structure is coupled to the peripheral circuit.

13. The method of claim 12, wherein forming the first semiconductor structure comprising the array of memory cells comprises:
forming a semiconductor body of the transistor in a semiconductor layer of the first semiconductor structure; and
forming a dielectric region extending through the semiconductor layer along the first direction.

14. The method of claim 13, wherein the first semiconductor structure comprises a first side and a second side opposite to the first side, the first side is closer to the semiconductor layer than the second side along the first direction, and forming the contact structure in the first semiconductor structure comprises:
forming a contact hole in the first semiconductor structure by etching the first semiconductor structure from the first side, wherein the contact hole extends through the dielectric region; and
forming the contact structure in the contact hole by depositing a conductive material into the contact hole.

15. The method of claim 14, further comprising:
stacking the first semiconductor structure on a carrier wafer before forming the contact hole, wherein the second side is in contact with the carrier wafer.

16. The method of claim 14, further comprising:
forming an interconnect layer in the first semiconductor structure, wherein the interconnect layer is coupled to the contact structure and comprises at least an interconnect line extending along a second direction perpendicular to the first direction and a vertical interconnect access (VIA) extending along the first direction.

17. The method of claim 14, wherein bonding the first semiconductor structure to the second semiconductor structure comprising:
bonding the first semiconductor structure to the second semiconductor structure through a bonding structure, wherein the bonding structure comprises conductive bonding pads and at least one dielectric material isolating the conductive bonding pads in a second direction perpendicular to the first direction, and the first side is between the second side and the bonding structure.

18. The method of claim 14, further comprising:
forming a trench extending from the second side of the first semiconductor structure into the first semiconductor structure;
forming a conductive contact structure in the trench by depositing a conductive material in the trench, wherein the conductive contact structure is coupled to the storage structure.

19. A memory system, comprising:
a memory device; and
a memory controller coupled to the memory device and configured to control the memory device, wherein:
the memory device comprising a first semiconductor structure and a second semiconductor structure connected together;
the first semiconductor structure comprises a first contact structure extending along the first direction and an array of memory cells;
the first contact structure comprises a first cross section and a second cross section both perpendicular to the first direction;
the first cross section is farther away from the second semiconductor structure than the second cross section along the first direction; and
a size of the first cross section is smaller than a size of the second cross section.

20. The memory system of claim 19, wherein the size of the first cross section is a maximum size of the first cross section along a second direction perpendicular to the first direction, and the size of the second cross section is a maximum size of the second cross section along the second direction.
